(19) United States
(12) Patent Application Publication
(10) Pub. No.: US 2025/0147092 A1
(43) Pub. Date: May 8, 2025

(54) Systems and Methods for Fault Location in Electrical Power Line Systems

(71) Applicant: Monash University, Clayton (AU)

(72) Inventors: Reza Razzaghi, Clayton (AU); David Flynn, Clayton (AU); Lachlan Andrew, Melbourne (AU)

(73) Assignee: Monash University, Clayton (AU)

(21) Appl. No.: 18/837,533

(22) PCT Filed: Feb. 10, 2023
(86) PCT No.: PCT/AU2023/050092

§ 371 Date: Aug. 9, 2024

(30) Foreign Application Priority Data
Feb. 10, 2022 (AU) 2022900273

(51) Int. Cl. G01R 31/08

(52) U.S. Cl. CPC G01R 31/086; G01R 31/088

(57) ABSTRACT

A method for estimating fault location in an electrical power line system (PLS) is provided. The method includes receiving an observed signal caused by a real fault in the PLS. The observed signal is measured at a real observation point in the PLS. The real fault has occurred at one of two or more real locations in the PLS; accessing a library representing model signals between model guessed fault locations and a model observation point in a network model of the PLS; selecting a model GFL by: (i) calculating metrics for the model signals by processing the model signals with the observed signal, and/or (ii) selecting the model GFL corresponding to a highest calculated metric; estimating a fault location of real locations in the PLS based on a corresponding location of the selected model GFL; and sending the estimated fault location to an external management system.

### RELATED APPLICATIONS

The present application is related to Australian Provisional Patent Application No. 2022900273, the originally filed patent specification of which is hereby incorporated herein by reference in its entirety.

### TECHNICAL FIELD

The present disclosure relates to the field of electrical power networks, more particularly to systems and methods of fault location in electrical power line systems (PLS), e.g., three-phase electrical transmission networks, three-phase electrical distribution networks, single phase networks, and Single Wire Earth Return (SWER) line systems.

### BACKGROUND

Methods for determining the location of a fault are important in the operation of electrical (electric) power line systems, which can include power transmission and distribution systems, as faults have a significant influence on the security, reliability and quality of supply. Failure to quickly and accurately identify, locate and manage/repair faults can have deleterious effects such as environmental damage (e.g., starting bushfires or wildfires), economic harm (due to businesses and transport systems being without power), and endangering life (e.g., from failed medical services, fires, etc.). In transmission networks, a fault location method is necessary to identify the faulted line and adequately reconfigure the network to anticipate any severe cascading consequences. In distribution networks, the fault location methods are more relevant to the reliability and quality of service in relation to the duration of an interruption caused by a permanent fault, e.g., to reduce power outages for customers.

Increased use of distributed generation is considered to be desirable due to the potential of distributed generation to improve quality, efficiency and reliability of power supply, as well as its facilitation of the use of renewable energy sources. However, the integration of distributed generation into existing networks may introduce some technical difficulties. This calls for fast and accurate fault location methods aimed at minimizing network service restoration time, and consequently minimizing unsupplied power in the event of a fault.

A number of fault location methods have been previously proposed in relation to both transmission and distribution power networks. Two main categories are (i) methods that analyse pre- and post-fault voltage/current phasors; and (ii) methods that analyse fault-originated electromagnetic transients of currents and/or voltages (e.g., in the form of travelling waves generated by the fault).

Previous category (i) methods suffer from requiring estimations of the post-fault impedances of the fault, which is unreliable with increasingly distributed generation in recent years. Such previously proposed methods often relied on an estimation of the post-fault impedance observed at observation points, usually located in primary substations, and the integration of distributed generation affects the accuracy of these methods.

Previous category (ii) methods often require multiple measurement points to be time synchronized, or otherwise fail to obtain accurate locations on large, complex networks, which is particularly relevant when the fault current is small. Such methods may need undesirably large bandwidth measuring systems in order to measure the high frequency transient signals.

It is desired to address or ameliorate one or more disadvantages or limitations associated with the prior art, or to at least provide a useful alternative.

### SUMMARY

According to at least one embodiment of the present invention there is provided a method of fault location in an electrical power line system (PLS), the method including:
a. receiving at least one observed signal (wherein the at least one observed signal may include a plurality of observed signals) caused by a real fault in the PLS, wherein the or each observed signal is measured (including has been measured) at a real observation point in the PLS, and wherein the real fault has occurred at one of two or more real locations in the PLS;
b. accessing a library representing a plurality of model signals (representing electrical characteristics) between model guessed fault locations (“model GFLs”, which correspond to the real locations) and at least one model observation point (which corresponds to at least one of the real observation points) in a network model of the PLS;
c. selecting at least one of the model GFLs by:
   (i) calculating metrics for the model signals by processing the model signals with the or each observed signal according to a pre-selected mathematical relationship/operation, and/or
   (ii) selecting the at least one model GFL corresponding to at least one highest one of the calculated metrics;
d. estimating at least one fault location of the two or more real locations in the PLS based on at least one corresponding location of the at least one selected model GFL; and
e. sending the or each estimated fault location to an external management system to respond to the real fault.

The model signals may include expected fault signals (or “model fault signals”) at the at least one model observation point (e.g., generated from the network model and/or from real measurements of the real network). Calculating the metrics and selecting the at least one model GFL may include selecting at least a most similar one of the plurality of model signals to the or each observed signal, and selecting the model GFL(s) that correspond to the selected model signal(s). The metrics may include similarity metrics representing a similarity between each expected fault signal and the or each observed signal. The (“first”) pre-selected mathematical relationship/operation may include: a correlation between each expected fault signal and the or each recorded observed signal; and/or energy in a difference signal (energy in a difference signal) between each expected fault signal and the or each recorded observed signal.

The model signals may include model transfer functions (labelled “h” herein, also referred to as “system responses”) between the model GFLs and the at least one model observation point (e.g., generated from the network model and/or from real measurements of the real network). Calculating the metrics and selecting the at least one model GFL may include determining guessed fault signals (labelled “r” herein) at the model GFLs for the or each observed signal (including by combining the or each observed signal with the model transfer functions), and selecting at least one of the model GFLs corresponding to at least one of the guessed fault signals having at least one property of the guessed fault signals (e.g., a numerical/statistical property), optionally a highest determined numerical value of the property. The metrics may include numerical values of a selected property of the (N×M) guessed fault signals (“r”) determined by combining the or each observed signal with each of the (N×M) model transfer functions (“h”). Thus the selecting the at least one model GFL may include: determining the guessed fault signals (labelled “r” herein) at the model GFLs (for the or each observed signal) by combining the or each observed signal with each model transfer function, and determining a numerical value of the property for each guessed fault signal (“r”), and selecting the at least one model GFL corresponding to the highest of the numerical values. The values of the property of the guessed fault signals (“r”), including a reduced subset of the guessed fault signals, are determined according to the mathematical relationship/operation, including a mathematical relationship with a numerical/statistical operation. The (“second”) pre-selected mathematical relationship/operation may include: the combining of each model transfer function and the recorded observed signal, optionally including a reverse time convolution of the or each observed signal and/or a derivative of the or each observed signal; and/or a numerical/statistical operator for the combining (or “combination”), optionally selection of a central value and/or determining an average value.

The model signals represent the electrical characteristics in the PLS between the guessed fault locations and the observation points (expressed in a pairwise fashion), e.g., for “M” fault locations and “N” observation points, there are at least M×N model signals in the library. The model signals may be generated from the network model and/or from real measurements of the real network.

According to at least one embodiment of the present invention there is further provided a method of generating a plurality of model signals at a real observation point of an electrical power line system (PLS), the method including:
a. defining a network model of the PLS including:
   (i) one or more model observation points corresponding to the real observation points of the PLS, and
   (ii) a plurality of model guessed fault locations (model GFLs) corresponding to respective real expected fault locations (real GFLs) in the PLS;
b. injecting a test pulse at the model observation point of the network model;
c. recording respective test responses to the test pulse at the model GFLs;
d. calculating, from the recorded test responses, respective model signals for each model GFL paired with the or each model observation point; and
e. generating a library representing the plurality of model signals for locating a real fault in the PLS based on estimating a location of the real fault by selecting at least one of the model GFLs that corresponds to at least one of the model signals selected by calculating metrics for the model signals (respectively) by processing the model signals with at least one observed signal caused by the real fault at the real observation point according to a pre-selected mathematical relationship/operation.

The model signals may include expected fault signals (or “model fault signals”), e.g., generated from the network model and/or from real measurements of the real network. The calculating may include calculating, from the recorded test responses, respective expected fault signals at the model GFLs. The metrics may include similarity metrics representing a similarity between each expected fault signals and the or each observed signal. The selecting at least one of the model GFLs that corresponds to at least one of the model signals may include selecting a most similar one of the plurality of expected fault signals to the observed signal by selecting an expected fault signal with a highest value of the similarity metrics.

The model signals may include model transfer functions (labelled “h” herein, also referred to as “system responses”) between the model GFLs and model observation points (e.g., generated from the network model and/or from real measurements of the real network). The calculating may include calculating, from the recorded test responses, respective model transfer functions between the model GFLs and model observation points. The metrics may include numerical values of a selected property of (N×M) guessed fault signals (“r”) at the model GLFs. The locating may locating include a real fault in the PLS by determining guessed fault signals (“r”) at the model GFLs for an observed signal (including by combining the or each observed signal with the model transfer functions), and selecting at least one of the model GFLs based on at least one property of guessed fault signals.

According to at least one embodiment of the present invention there is further provided a computer-readable storage medium having stored thereon computer-executable instructions that cause a computing system to execute the above methods.

According to at least one embodiment of the present invention there is further provided a system for fault location in an electrical power line system (PLS), the system including: a computing system configured to execute the above methods; a voltage monitoring system attached to the PLS configured to monitor the observed signal; and a data acquisition system configured to send the observed signal from the voltage monitoring system to the computing system.

### BRIEF DESCRIPTION OF THE DRAWINGS

Preferred embodiments of the present invention are hereinafter described, by way of non-limiting example only, with reference to the accompanying drawings, in which:

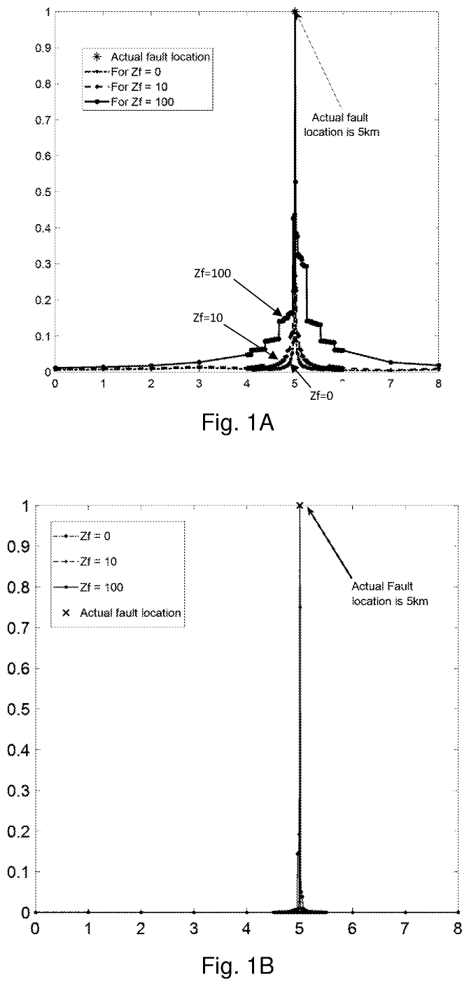

a. FIGS. 1A-1B show a response, tested on a simple one line system, of the metrics in Appendix A and B. FIG. 1A shows the response of metric m₁; and FIG. 1B shows the response of metric m₂. The metrics have been normalized over all guessed fault locations. The x-axis denotes the guessed fault locations.

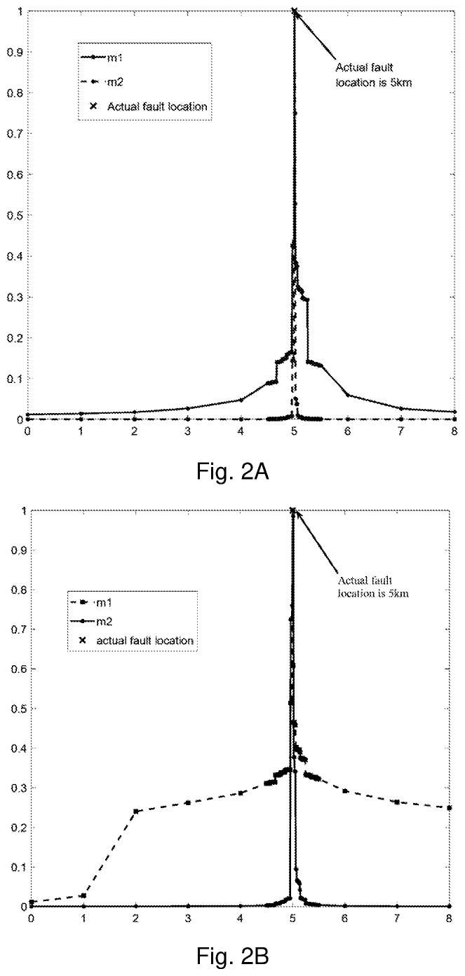

b. FIGS. 2A-2B show a comparison response of the metrics m₁ and m₂, for Z_{f}=100Ω, and Z_{f}=1000Ω respectively. The metrics have been normalized over all guessed fault locations. The x axis denotes the guessed fault locations.

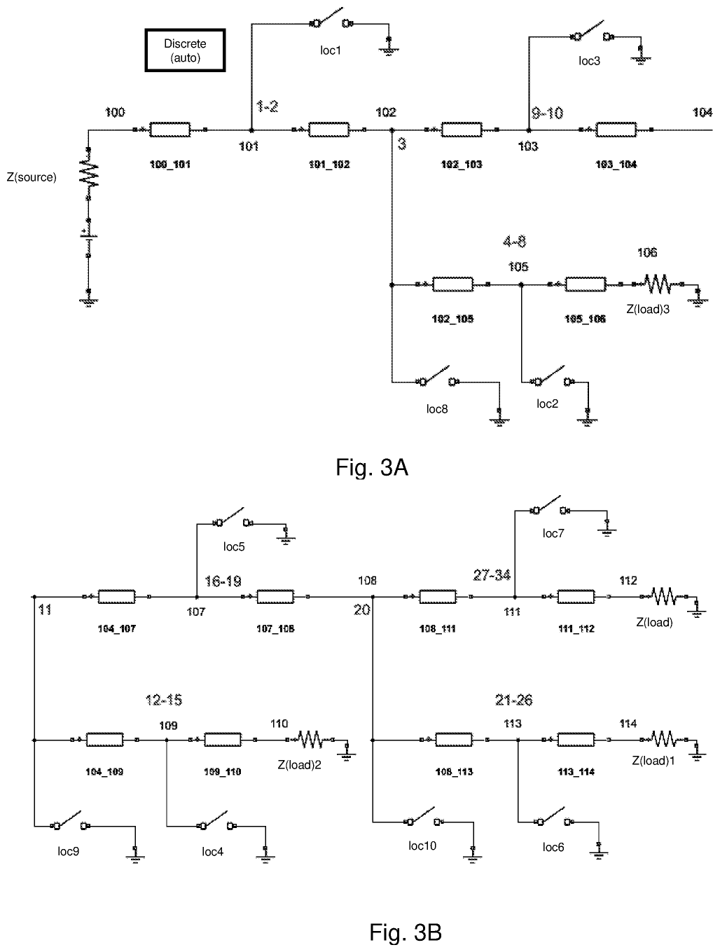

c. FIGS. 3A and 3B together show a schematic of a network model used to test different metrics.

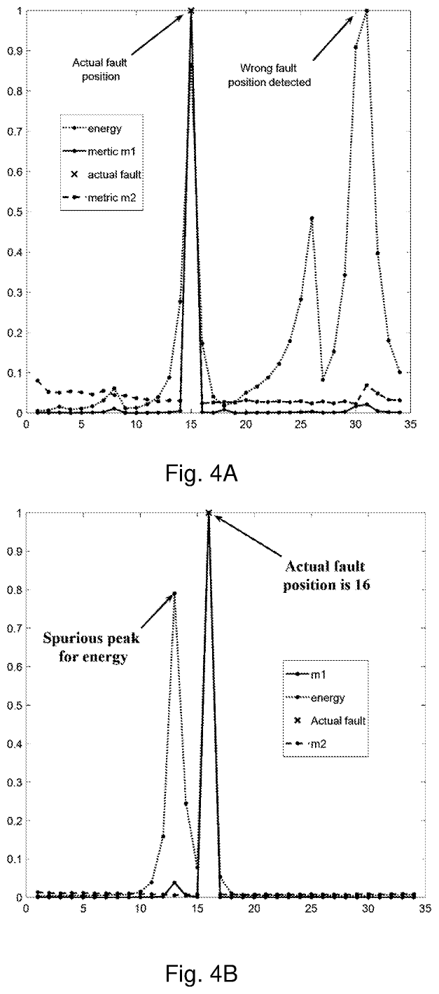

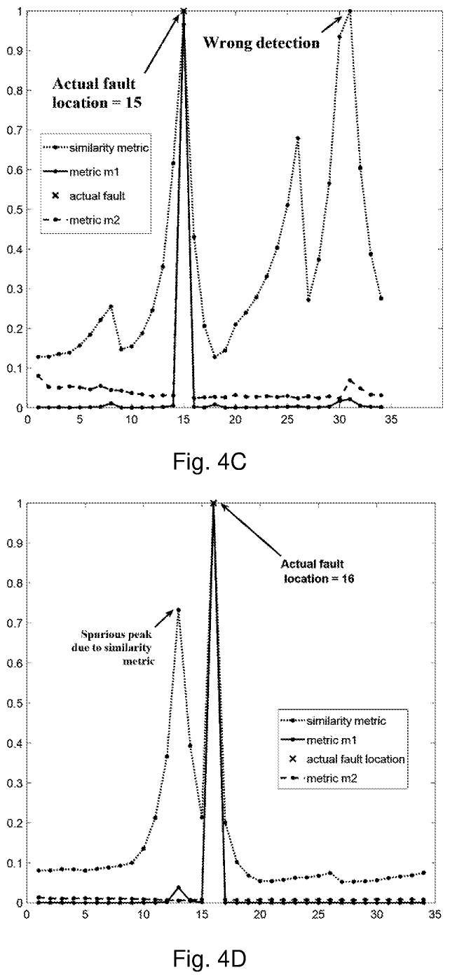

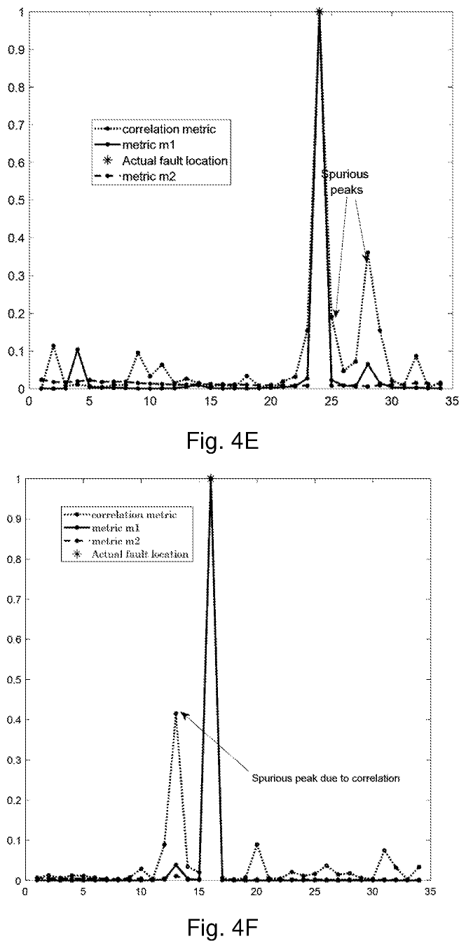

d. FIGS. 4A to 4F show the performance of the metrics m₁; and m₂ compared with existing methods for a number of actual fault locations in the system shown in FIGS. 3A and 3B. The metrics have been normalized over all guessed fault locations. The x-axis denotes the guessed fault locations.

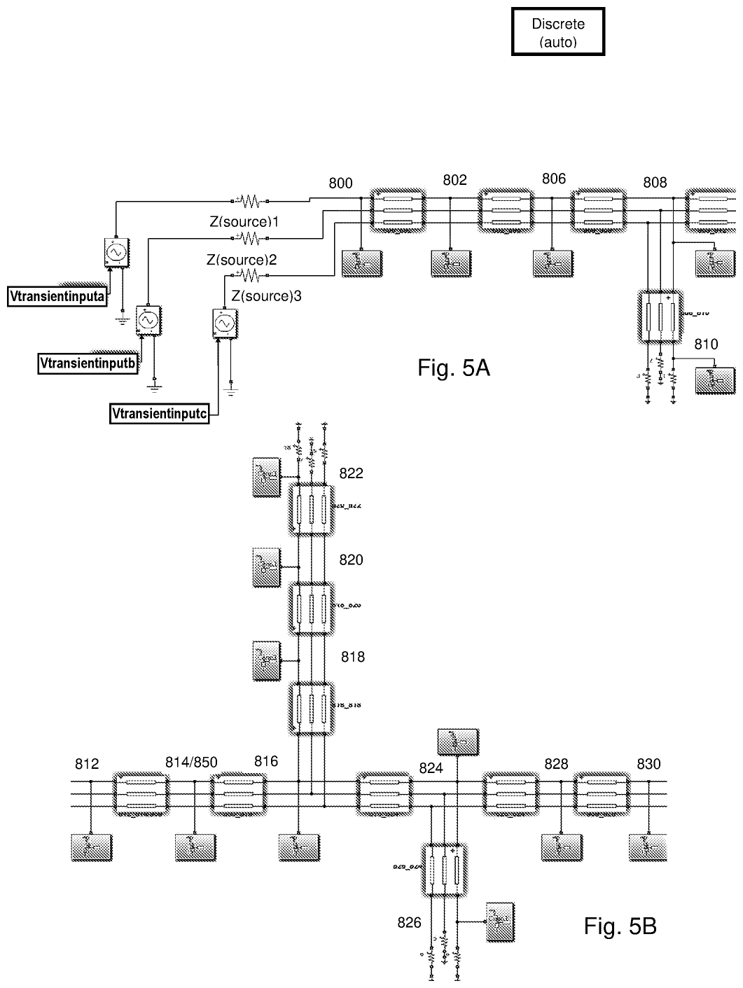

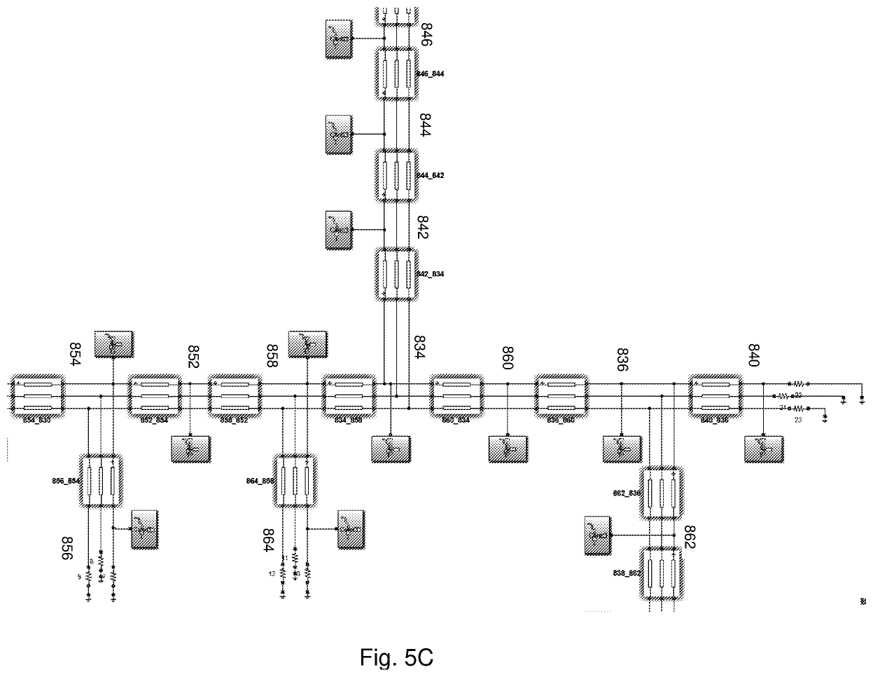

e. FIGS. 5A to 5C together show a schematic of an IEEE 34-bus system used to test different metrics.

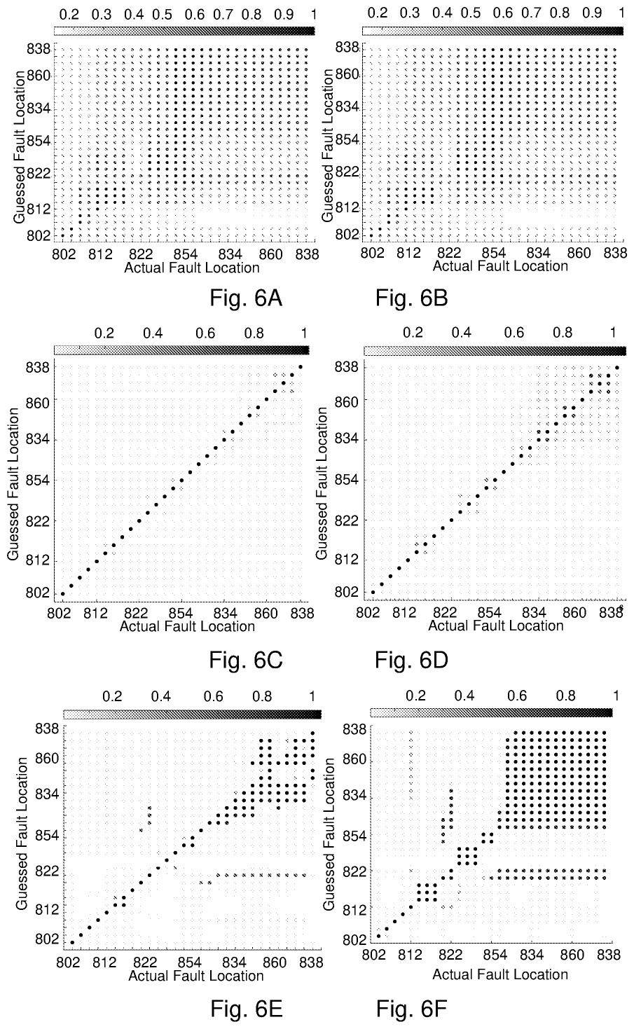

f. FIGS. 6A-6E show a comparison of the accuracy of an existing method based on the Fault Current Signal Energy (FCSE) (FIGS. 6A-6B); the hereinafter described method using metric m₂ (FIGS. 6C-6D); and 6(e)-(f) the hereinafter described method using m₁ (FIGS. 6E-6F). The x-axis denotes the actual fault location. The y-axis denotes the guessed fault locations.

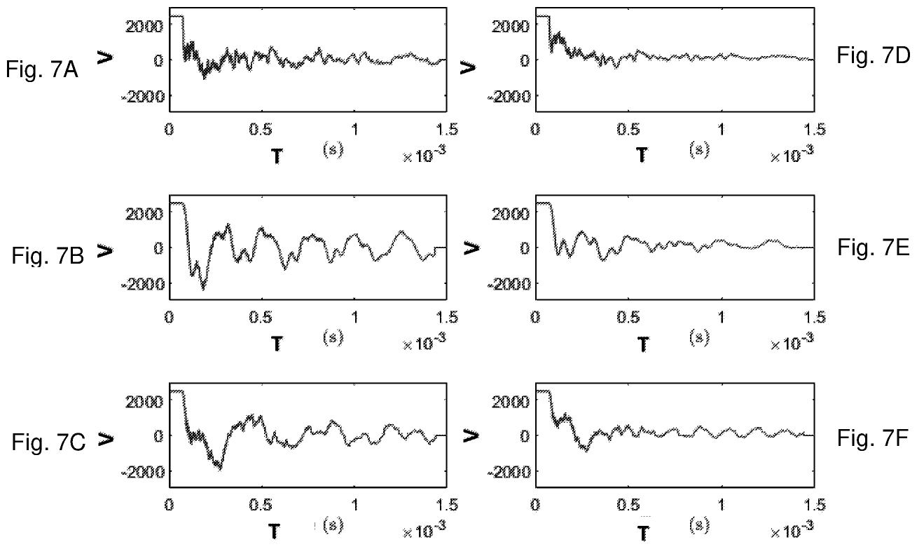

g. FIGS. 7A to 7C are a voltage-time graphs of three observed signals, at three different respective observation locations (from respective voltage/current sensors), obtained in a power line system (PLS) network from three respective sensors, with a fault impedance of 10 Ohm;

h. FIGS. 7D to 7F is a voltage-time graphs of three observed signals, at three different respective observation locations (from respective voltage/current sensors), obtained in a power line system (PLS) network from three respective sensors, with a fault impedance of 100 Ohm;

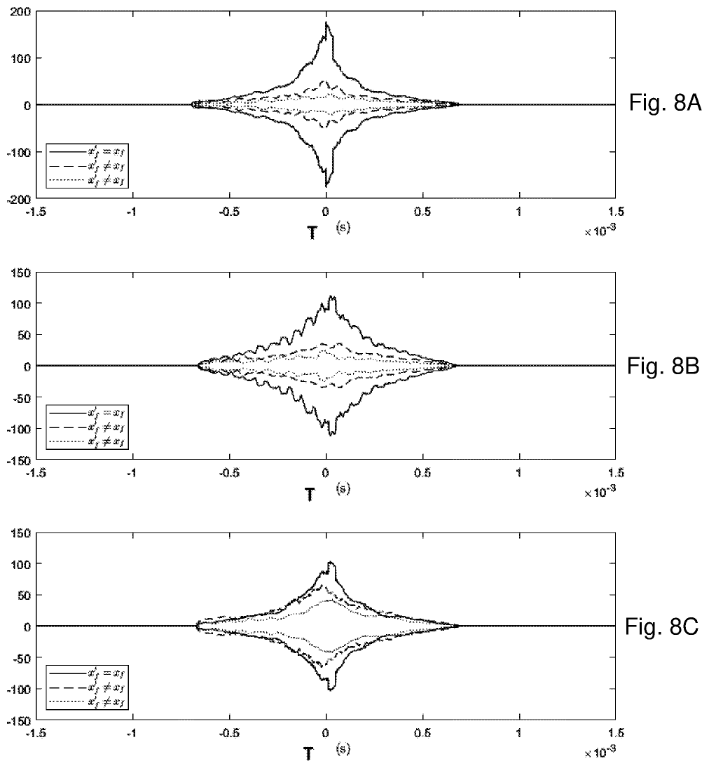

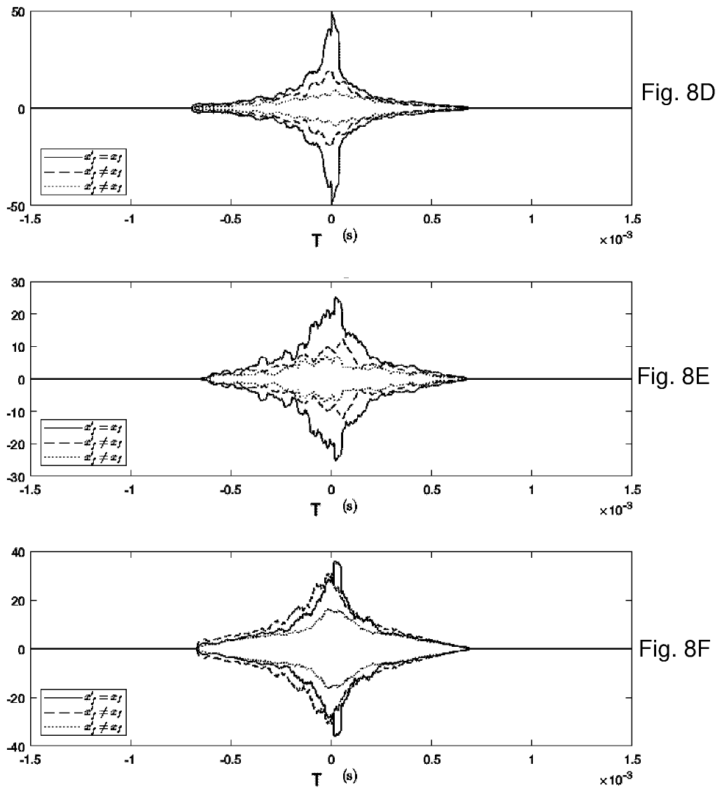

i. FIGS. 8A to 8C are envelopes of the voltage-time graphs of 3 calculated guessed fault signals (corresponding to 3 model fault locations) for each observed signal in FIGS. 7A to 7C with the function “f” being in the form of a derivative operator;

j. FIGS. 8D to 8F are envelopes of the voltage-time graphs of 3 calculated guessed fault signals (corresponding to 3 the model fault locations) for each observed signal in FIGS. 7D to 7F with the function “f” being in the form of a derivative operator;

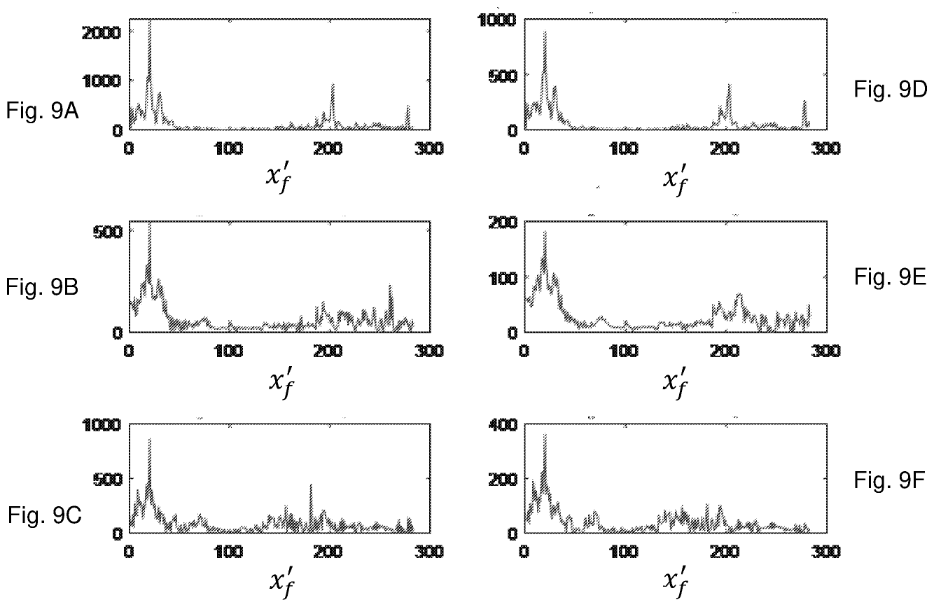

k. FIGS. 9A to 9C are plots of the sets of (real value) numbers (on the Y axis), each representing a vector of M values across the model GFLs (“x”, on the X axis) for calculated guessed fault signals (in FIGS. 8A to 8C, and other model GFLs) from the 3 observed signals in FIGS. 7A to 7C;

l. FIGS. 9D to 9F are plot of the sets of (real value) numbers (on the Y axis), each representing a vector of M values across the possible fault locations (“x”, on the X axis) for calculated guessed fault signals (in FIGS. 8D to 8F, and other model GFLs) for the 3 observed signals in FIGS. 7D to 7F;

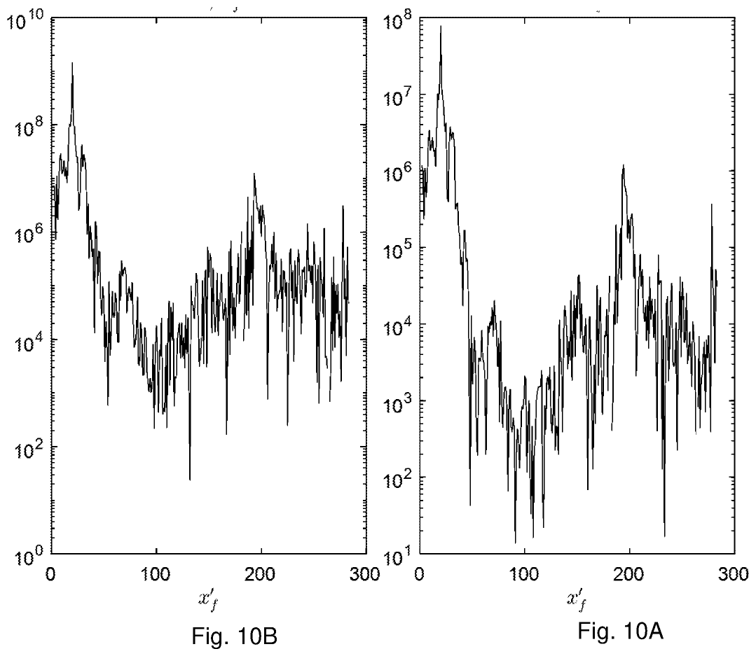

m. FIGS. 10A and 10B are reduced subsets of the M real valued numbers in FIGS. 9A to 9C, and FIGS. 9D to 9F, respectively;

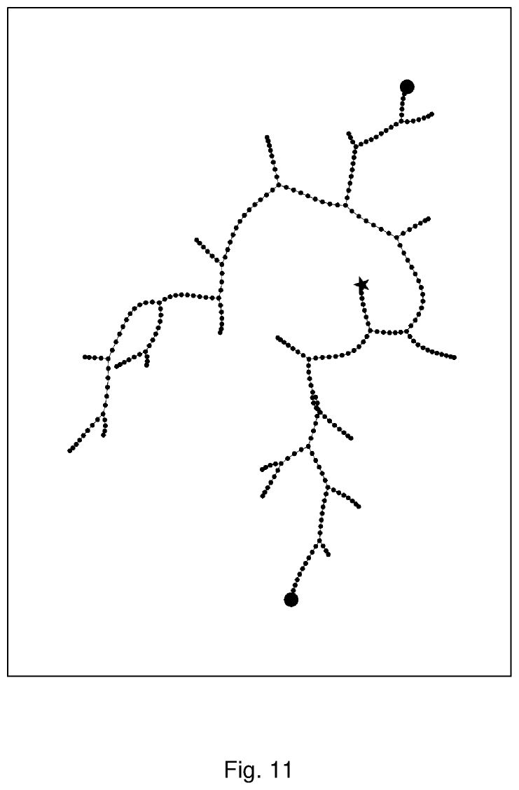

n. FIG. 11 is a diagram of the network under test with circular dots representing some possible observation points/locations and the star representing a substation; and

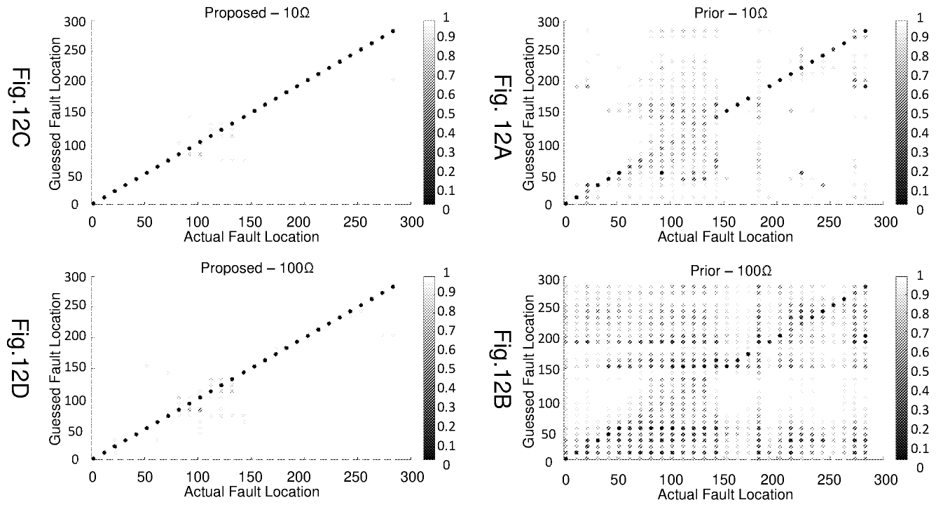

o. FIGS. 12A-12D are plots of guessed fault location (Y-axis) and actual fault location (X-axis) to show a comparison of accuracies of a previous method based on the Fault Current Signal Energy (FCSE) (FIGS. 12A and 12B); and the herein-described method using statistical properties of the guessed fault signal (FIGS. 12C and 12.D).

### DETAILED DESCRIPTION

### Overview

Described herein is a method of estimating a location of a real fault in an electrical power line system (PLS), which is defined as the whole of, or a selected portion of, an actual electrical network, such as a transmission or distribution network. Where the PLS is a selected portion of the actual electrical network, the PLS is generally bounded by transformers. The PLS may be a high-voltage network at 66 kV, a medium voltage network, e.g., at 22 kV, 18 kV, 11 kV, 6.6 kV, or a low-voltage network at 415V.

The method includes the following steps:
a. receiving at least one observed signal (labelled “s” herein with subscripts “1” to “N”) caused by a real fault in an electrical power line system (PLS), wherein the observed signal is measured at one or more real observation points (labelled “1” to “N” herein) in the PLS, and wherein the real fault has occurred at one of two or more real locations (labelled “x” with subscripts “1” to “M” herein) in the PLS;
b. accessing a library representing a plurality of model signals (representing electrical characteristics) between respective model guessed fault locations (model GFLs, which correspond to the real locations, and may be referred to as “possible fault locations”) and model observation points (which correspond to the real observation points) in a network model of the PLS-thus the number of model signals in the library is at least equal to the number of model observation points “N” times the number of model GFLs “M”, or “N×M”; wherein the model signals include (i) expected fault signals (or “model fault signals”) (e.g., generated from the network model and/or from real measurements of the real network), and/or (ii) model transfer functions (labelled “h” herein, also referred to as “system responses”) between the model GFLs and model observation points (e.g., generated from the network model and/or from real measurements of the real network);
c. selecting at least one of the model GFLs by: (i) selecting at least a most similar one of the plurality of model signals to the observed signal, and selecting the model GFL(s) that correspond to the selected model signal(s), and/or (ii) determining guessed fault signals (labelled “r” herein) at the model GFLs for each observed signal (including by combining the observed signal with the model transfer functions, thus generating at least “N×M” guessed fault signals), selecting at least one of the model GFLs based on at least one property (e.g., a numerical/statistical property) of the guessed fault signals;
d. estimating a fault location of the real fault in the PLS that matches the model GFL(s); and
e. sending the estimated fault location to an external management system to respond to the real fault.

The selecting of the at least one of the model GFLs, covering both the expected fault signals (“first technique”) and the model transfer functions “h” (“second technique”), may be summarised as follows:
a. calculating metrics for the model signals by processing the model signals with the or each observed signal according to a pre-selected mathematical relationship/operation, and
b. selecting the at least one model GFL corresponding to at least one highest of the calculated metrics.

The pre-selected mathematical relationship/operation represents electrical propagation between the real locations and the real observation points in the PLS, and may include representing (forward) propagation from each real location to the real observation points (e.g., by way of a correlation or a difference energy), or (reverse) propagation from each real observation point to the real location (e.g., by way of reverse time convolution).

When the model signals include the expected fault signals (“first technique”), the metrics may include similarity metrics representing a similarity between each expected fault signals and the or each observed signal.

When the model signals may include model transfer functions (“second technique”), the metrics may include numerical values of a selected property of (N×M) guessed fault signals (“r”) generated by combining the or each observed signal with each of the (N×M) model transfer functions (“h”), and the selecting the at least one model GFLs may include: determining guessed fault signals (labelled “r” herein) at the model GFLs (for the or each observed signal) by combining the or each observed signal with each model transfer function, and determining a numerical value of the property for each guessed fault signals (“r”), and selecting the at least one model GFL corresponding to the highest of the numerical values. The values of the property of the guessed fault signals (“r”) are determined according to a mathematical relationship/operation, including a mathematical relationship with a numerical/statistical operation.

The model signals represent the electrical characteristics in the PLS between the guessed fault locations and the observation points (expressed in a pairwise fashion), e.g., for “M” fault locations and “N” observation points, there are at least M×N model signals in the library. The set of model transfer functions (“h”) is generated by injecting a short (instantaneous) pulse and measuring the response (in the simulated environment), which can include injecting the pulse at the model observation point and measuring the response at the model GFL, or by injecting the pulse at the model GFL and measuring the response at the model observation point.

The real fault occurs at an actual fault location of the PLS. The method identifies/determines/outputs the real GFL (or real GLFs) of the PLS closest (i.e., most proximal) to the actual fault location. The model GFLs of the network model correspond to respective real GFLs of the PLS.

The method may be used to locate different types of faults, including single-line-to-ground, line-to-line or three-phase faults.

The occurrence of the fault at the actual fault location generates electromagnetic transients which can be recorded as the observed signals at the one or more (up to “N”) real observation points, e.g., points in different part of the network indicated by circles in FIG. 11. The post-fault electromagnetic transients, observed within milliseconds of the fault, are generally not affected by industrial-frequency power injections of distributed sources; thus the electromagnetic transients may be referred to as “high frequency electromagnetic transients”. The one or more real observation points are locations in the PLS that are different from the actual fault location, and different from each other. In some embodiments each real observation point may be associated with a zone. Depending on the characteristics of the PLS, there may be real observation points at selected locations and distances on the lines of the PLS: the number and the locations of the observation points are selected based on the characteristics of the network/PLS (e.g., network complexity), and on the accuracy of the location determination required. Real observation points may be located at substations, at transformers along a feeder, and/or at the end of a line branch. At one of the real observation points, the observed signal may be recorded using a single sensor-thus the observed signal(s) may be referred to as “recorded signal(s)”, and the observation point(s) may be referred to as “sensor points” or “locations”. The substation may supply multiple power lines.

For each real fault, each observed signal (“s”) is a time series voltage waveform or time series current waveform corresponding to the different electrical phases of the system, e.g., as shown in FIGS. 7A to 7F. For example, in a single phase or SWER system, the observed signal will have one waveform; and in a three-phase system, the observed signal will have three waveforms. Measurements of the observed signal may be initiated after a pre-fault signal, and may be recorded for a few milliseconds (typically a few tens of milliseconds). When there are two or more observed signals (up to “N”), the two or more observed signals are unsynchronized, or non-synchronized, due to being observed/measured using unsynchronized sensors.

The steps of accessing the library, selecting the best-corresponding model signal, selecting the appropriate model GFL, and sending this to the external management system, are performed by a computing system that executes computer-executable instructions in computer-readable storage. The computer-executable instructions are configured to control the computing system, which can be a cloud computing system (i.e., a commercially available computing system accessible over a commercial network), a commercially available computer server, or an embedded computer system including analogue-to-digital converters, to perform these steps of the method. Example snippets of source code that defines the computer-executable instructions are set out in computer program appendix appended hereto (Appendix). The computing system is thus configured by inclusion of the computer-executable instructions to execute the steps of accessing the library, selecting the most similar expected fault signal, selecting the appropriate model GFL, and sending this to the external management system. The external management system may be a distribution management system (DMS) and/or a Supervisory Control and Data Acquisition System (SCADA).

The computer-executable instructions comprise, for example, instructions and data which cause a general purpose processing unit, special purpose processing unit, and/or special purpose microprocessor device(s) to perform a certain function or group of functions. The computer-executable instructions may be, for example, binaries, intermediate format instructions such as assembly language, or even source code. The instructions to perform the acts can be stored on one medium, or could be stored across multiple media, so that the instructions appear collectively on the one or more computer-readable storage medium/media, regardless of whether all of the instructions are on the same media.

Computer readable storage excludes propagated signals as such, can be accessed by the computing system, and can include volatile and non-volatile internal and/or external media that is removable and/or non-removable. For the computing system described hereinbefore, the various types of storage media accommodate the storage of data in any suitable digital format. It should be appreciated by those skilled in the art that other types of computer readable media could be employed, such as solid state drives, magnetic tape, flash memory cards, flash drives, cartridges, and the like, for storing computer-executable instructions for performing the methods described herein.

Described herein is a system that includes the computing system described hereinbefore. The system operates to execute the method automatically when the observed signal is received. The system may use a fault detection algorithm in order to detect the occurrence of a fault and initiate the method for fault location.

The method described herein includes recording the observed signal at the real observation point, where the observed signal is caused by the real fault in the PLS. To this end, the system includes line-monitoring units, medium voltage high-bandwidth voltage/current sensors (e.g., sensors manufactured by Altea Solutions), a digitiser (e.g., the NI-9775 Digitizer Module produced by National Instruments) and a controller including the triggering system and data storage (e.g., cRIO-9082 produced by National Instruments).

The system may also include a secure high bandwidth data acquisition system configured to send data representing the recorded observed signal to the computing system.

### Comparing Expected Fault Signals To Observed Signal (“First Technique”)

As described hereinbefore, the method described herein may include selecting the most similar one of the plurality of model fault signals (in the form of expected fault signals) to the observed signal by comparing the observed signal to the plurality of expected fault signals, and estimating the location of the real fault in the PLS by selecting the model GFL that corresponds to the most similar one of the plurality of expected fault signals according to a selected similarity metric.

The observed signal may be compared to each of the plurality of expected fault signals to generate a plurality of respective similarity values according to the selected similarity metric. The similarity values demonstrate the highest similarity for at least the expected fault signal that corresponds to a model GFL (and therefore a real GFL) that is same as the actual fault location.

The similarity between the recorded observed signal and each of the expected fault signals is quantified using the selected similarity metric. Thus in the described method, the at least a most similar one of the plurality of expected fault signals to the observed signal is selected by:
a. comparing the observed signal to the plurality of expected fault signals to generate a plurality of respective similarity values according to a selected similarity metric, and
b. selecting at least one of the plurality of expected fault signals corresponding to a selected one of the plurality of similarity values representing a highest similarity according to the selected similarity metric.

The observed signal is a (time) series of values representing the observed signal, and each expected fault signal is a series of values representing the expected fault signal. The estimated location of the real fault is the real GFL corresponding to the model GFL of the expected fault signal with the highest similarity value when compared to the observed signal using the selected similarity metric. Two possible metrics are hereinafter described: other metrics, including variations of these, may also be used.

First Metric “m1”

In at least one embodiment the metric is a first metric, m₁, which is a correlation between each expected fault signal and the recorded observed signal. The correlation should be maximal for the expected fault signal corresponding to the GFL closest to the actual fault location, without requiring any time shift of the signals. However, this is not necessarily the case in larger systems, where a delay might come about in recording the observed signal caused by the real fault. Therefore, the correlation may be taken to be the maximum of the values obtained by considering a maximum allowed shift. This value, in itself, is an indicator of the actual fault location. For the first metric m₁, time delay may also be calculated in order to remove spurious peaks that indicate incorrect fault locations. The time delay may be defined as a sample shift at which the correlation reaches its maximum. Consequently, the time delay, or more specifically the sample delay, may only be relevant when the correlation is high enough. The similarity indicates that the time delay should be at a minimum for the expected fault signal corresponding to the GFL closest to the actual fault location. m₁ may be expressed as:

$${m}_{1} = \frac{log log ( 1 - correlatio )}{1 + \vert time ( sample ) delay \vert} \qquad ( 13 )$$

The similarity values according to the first metric may be generated for each expected fault signal by the following method:
a. calculating a time-domain correlation signal (e.g., a series of values) representing a correlation between the observed signal (e.g., a series of values representing the observed signal) and the expected fault signal (e.g., a series of values representing the expected fault signal) using a correlation function, e.g., the “xcov” function in MATLAB (see Appendix A line 162);
b. calculating a peak value of the correlation signal, i.e., the maximum absolute value of the series of value, e.g., using the “max” function in MATLAB, and the time shift associated with the peak value of the correlation signal (see Appendix A line 163);
c. calculating a time delay at which the peak value appears in the correlation signal, i.e., the time delay of the maximum correlation value, e.g., using the “xcov” and “max” functions in MATLAB (see Appendix A lines 162 and 164); and
d. calculating the similarity value based on the peak correlation value and an inverse relationship with the time delay: e.g., using Equation (13), i.e., the absolute value of the logarithm of one minus the peak value of the correlation signal, divided by one plus the absolute value of the time delay (see Appendix A line 167).

Accordingly, the similarity values for the first metric may be based on a ratio between an extremum of the correlation signal between the expected fault signal and recorded observed signal, and the time delay for the extremum.

The steps of the above method for generating the similarity values are executed automatically by the system described herein.

Second Metric “m2”

In at least one embodiment the metric may be a second metric m₂, which is the energy in a difference signal between each expected fault signal and the recorded observed signal, being an error between each expected fault signal and the recorded observed signal. For m₂, each expected fault signal is aligned with the recorded observed signal, based on the delays described above. The error between the two signals may then be calculated by subtracting one from the other. In an AC system, the calculated error will have a 50 Hz component. For m₂, an important part of the difference signal may be a band that includes various switching frequencies possible for various guessed fault locations. An appropriate bandpass filter for the PLS may be used to extract the important part of the difference signal. The bandpass filter is selected such that it preserves frequency components associated with switching frequencies in the PLS, which can be pre-calculated from analysis of the parameters of the PLS, e.g. using the methods described in reference [7]. Using m₂, the energy of the signal is minimised (and the inverse of this quantity is maximised) for the expected fault signal corresponding to the GFL closest to the actual fault location. The metric m₂ may be defined as:

$${m}_{2} = \frac{1}{1 + \vert error energy \vert} or \frac{1}{0 \text{.1} + \vert error energy \vert} \qquad ( 14 )$$

The choice between 0.1 and 1 depends on the precision of the measurement unit. In some cases, using 1 may be sufficient.

The similarity values according to the second metric may be generated for each expected fault signal by the following method:
a. generating an aligned observed signal (e.g., a series of values representing the observed signal) and/or an aligned expected fault signal (e.g., a series of values representing the expected fault signal), based on the observed signal and the expected fault signal, e.g., by shifting the earlier of the two signals to be aligned with the later of the signals, e.g., by using the MATLAB function “alignsignals” to delay the earlier signal (see Appendix B line 154).
b. calculating a difference signal (e.g., a series of values) representing the difference between the aligned observed signal and the aligned expected fault signal at each time point (i.e., the difference signal is a time-domain signal of the differences between the aligned observed signal and the aligned expected fault signal over time), e.g., using the MATLAB function “−”, e.g., a(xG)−b(xG) (see Appendix B line 155);
c. generating an error signal by filtering the difference signal using the bandpass filter (BPF), defined by a band pass of frequencies selected according to the topology and electrical characteristics of the PLS, e.g., by convolving the difference signal with the time-domain BPF response (generated as a reverse-Fourier transform of the frequency-domain BPF), e.g., using the MATLAB command “conv” (see Appendix B line 157);
d. calculating the error energy value, i.e., the energy in the error signal, as a summation of the squared values of the error signal, e.g., using the MATLAB commands for squaring each value and “sum” of the squared values (see Appendix B line 159); and
e. calculating the similarity value based on an inverse relationship with the error energy value, e.g., using Equation (14), i.e., the inverse of the following: one plus the error energy (see Appendix B line 163).

Accordingly, the similarity values of the second metric may be proportional or inversely proportional to the energy in the error between the expected fault signal and the recorded observed signal.

The steps of the above method for generating the similarity values are executed automatically by the system described herein.

Implementation of the described method using the metric m₂ may allow for avoidance of spurious peaks, which may arise where the calculated time delay is less at points of low correlation using m₁.

Using a metric that avoids spurious peaks may increase the accuracy of the estimated location of the real fault as the only GFL with a guessed fault signal similar to the observed signal will be the closest GFL to the actual fault location.

### Calculating Expected Fault Signals And Model Transfer Function Using Network Model

The method described herein includes a method of generating the model signals in the form of the plurality of expected fault signals that are expected to be measured (or observed) at the real observation point of the PLS. This method includes the steps of:
a. defining the network model of the PLS including:
   i. the model observation point corresponding to a real observation point of the PLS, and
   ii. the plurality of model guessed fault locations (model GFLs) corresponding to respective real guessed fault locations (real GFLs) in the PLS;
b. injecting a test pulse at the model observation point of the network model;
c. recording respective test responses to the test pulse at the model GFLs;
d. calculating, from the recorded test responses, respective expected fault signals at the model GFLs; and
e. generating the library representing the plurality of expected fault signals for locating the real fault by selecting a most similar one of the plurality of expected fault signals to the observed signal caused by the real fault in the PLS at the real observation point, and estimating the fault location of the real fault by selecting the model GFL that corresponds to the most similar one of the plurality of expected fault signals.

The method includes generating the model signals in the form of the model transfer function by:
a. defining a network model of the PLS including:
   i. a model observation point corresponding to the real observation point of the PLS, and
   ii. a plurality of model guessed fault locations (model GFLs) corresponding to respective real expected fault locations (real GFLs) in the PLS;
b. injecting a test pulse at the model observation point of the network model;
c. recording respective test responses to the test pulse at the model GFLs;
d. calculating, from the recorded test responses, respective model transfer functions between the model GFLs and model observation points; and
e. generating a library representing the plurality of model signals for locating a real fault in the PLS by determining guessed fault signals (“r”) at the model GFLs for each observed signal (including by combining the observed signal with the model transfer functions), and selecting at least one of the model GFLs based on at least one (numerical/statistical) property of the guessed fault signals.

The method includes defining the network model, wherein the network model contains the model observation point corresponding to the real observation point and a plurality of model GFLs corresponding to the real GFLs of the PLS. Each real GFL is separate and distinct from the other real GFLs (i.e., mutually distinct), and is a potential or expected location of a fault in the PLS. The real GFLs may be uniformly distributed throughout the PLS. Alternatively, real GFLs can be selected to be the most likely locations for the real fault, such as cable junctions and different terminals. Various other methods for selecting the real GFLs are also possible. The network model is defined using the topology and the electrical parameters of the PLS. The network model of the PLS has substantially the same or equivalent electrical and size properties as the PLS, e.g., representing lengths of line sections, geometries of the conductors, topology of the PLS network, ground resistivity, parameters of transformers and regulators, etc.

The plurality of model signals corresponding to the real GFLs in the PLS are calculated using the network model for the PLS. The model observation point of the network model corresponds to the observation point of the PLS. Each of the plurality of model GFLs in the network model corresponds to one of the defined GFLs in the PLS.

The test pulse can be a voltage or current pulse injected at the model observation point, causing the response in the network model.

The test pulse may be a step fall to 0V with a fault impedance in series. This voltage may be defined as V_{f}(t)=1−u(t−t_{f}), where the fault occurs at time t_{f} and the pre-fault voltage is assumed to be 1 without loss of generality (u(t) denotes the usual unit step function). For each model GFL, the response to the test pulse at the model GFL is recorded and the expected fault signal for the corresponding real GFL in the PLS is calculated from the recorded response, e.g., by convolving the impulse response h_{RT}(t, <x₀, x_{G}>) with the assumed step fault voltage V_{f} (t), as shown in Equation (4):

$${V}_{ex}^{DT} ( t , < {x}_{0} , {x}_{G} > ) = {h}_{RT} ( t , < {x}_{0} , {x}_{G} > ) * {V}_{f} ( t ) \qquad ( 4 )$$

This step may be implemented using MATLAB commands as shown in Appendix A at line 160 and Appendix B at line 151.

The test pulse may be alternatively modelled using a different shape, e.g., as an exponential charge with a finite rise time. This test pulse may be defined as:

$${V}_{f} ( t ) = {V}_{0} ( 1 - {e}^{- \frac{t}{{T}_{r}}} ) .$$

In at least one embodiment, the plurality of calculated expected fault signals, or a representation thereof, may be stored in a data store.

According to the method described herein, the calculation of the plurality model signals may be performed offline and in advance, and the model signals stored in the data store. In the event of a fault, all that remains is to record the observed signal at the real observation point, determine probability/likelihood metrics, and select the corresponding model GFL and related real GFL for the at least one determined model GLF. Therefore, an implementation of the method described herein may be faster than existing methods.

In at least one embodiment, the stored data representing the plurality of model signals for the plurality of model GFLs may form a library of model signals for the real GFLs.

In at least one embodiment, calculation of the model signal for each model GFL may be achieved by convolving the respective recorded test response with a step signal (i.e., a short circuit).

In at least one embodiment the model signals may be expected fault transients Vₑₓ^{DT}(t), and the expected fault signal for each model GFL may be calculated by convolving the recorded test response at the corresponding model GFL and the step signal, which may be represented by V_{f}(t).

In at least one embodiment, recording of the test responses at the plurality of distinct model GFLs in the network model may involve calculation of current at the model GFLs. This may be desirable when the fault is a bolted fault and fault impedance Z_{f} is zero, meaning that the voltage at one or more of the model GFLs is undefined.

### Determining And Selecting Guessed Fault Signals (“Second Technique”)

As described hereinbefore, the method described herein may include selecting at least one of the model GFLs by:
a. determining the guessed fault signals (“r”) at the model GFLs for each observed signal, including by combining the observed signal with the model transfer functions, which may use the MATLAB ‘conv’ function, such (see Appendix C line 67), thus generating at least “N×M” guessed fault signals; and
b. selecting at least one of the model GFLs based on at least one property (e.g., a statistical property) of the guessed fault signals.

Thus, for each possible GFL, the method includes the fault generating the (N) observed signals (at the N observation points), which the method automatically reduces to a real number for each model GLF (thus M real numbers), which the method can then automatically reduce to at least one real number representing the most likely at least one model GFL. In other words, for N observed signals, there are M×N guessed fault signals (“r”), which give M×N real numbers, which are reduced to M real numbers, which can be reduced to 1 real number.

The model transfer functions (“h”) may be referred to as “system responses” (as described hereinbefore) or “re-computed/pre-simulated injections” because the method includes generating the library before receiving the observed signal(s). The library may be referred to as including a set of the model transfer functions (“h”), or an “injection set”.

The model transfer functions (“h”) may be generated from the network model by modelling transmission between the N observation points (which may be used as “injection locations” in the generation of the library) and the M model GLFs. Additionally or alternatively, the model transfer functions may generated from the real network by measuring transmission between the N observation points (which may be used as injection locations) and the M real GLFs. The set of the model transfer functions (“h”) can be generated by injecting a short (instantaneous) pulse and measuring the response (in the simulated environment and/or in the real network), which can include: (a) injecting the pulse at the model observation point and measuring the response at the model GFL, or (b) injecting the pulse at the model GFL and measuring the response at the model observation point; and then calculating each “h” based on a mathematic relationship between the short pulse (waveform) and the measured response (waveform), e.g., based on a ratio of the measured response over the short pulse in the complex frequency domain (or “H(s)”) for each pair of model observation point and model GFL.

The guessed fault signals (“r”) may be generated by combining the N observed signals with the model transfer functions (the “set”). The observed signals may be combined with the model transfer functions by a reverse time convolution of the observed signals (“s”), or signals derived from the observed signals (by a mathematical function “f” such as the derivative, e.g., using the ‘diff’ function in MATLAB (see Appendix C line 63)), with the transfer function set. The derived signals may be mathematical derivatives of the observed signals, thus the function “f” may be a derivative operator, generating guessed fault signals (“r”) symmetrically around a zero (time) value, as shown in FIGS. 8A to 8F. As mentioned above, the reverse time convolution represents a back-injection of the signal (“s”) into the PLS to each model GFL (or possible fault location, “x”).

Various options may be used to combine the (M×N) signals to generate the (M) real numbers representing corresponding numerical/statistical property/properties: (i) compute the numerical/statistical property in the form of a location metric for each sensor independently, and then combine these location metrics to determine a total prediction of the fault location; or (ii) compute the numerical/statistical properties by combining the “r” signals at a given fault location from all sensors/observation locations, and processing the combined signals to determine an overall likelihood for each location, and then compare the determined overall likelihoods of the possible fault locations to determine which has/have the highest likelihood(s) of being the model GFL.

A function (“g”) operates to reduce the vector “r” (representing the N observed numbers for a given GFL) down to a reduced subset, e.g., down to a single number, representing at least one real value number. This at least one real value number is compared by the method/system described herein to select/determine the most likely fault location(s). The real value numbers represent respective predictions of the real fault actually being at that corresponding model GFL. The method and system described herein is activated when a fault has occurred somewhere in the real PLS/network at or substantially close to a model GFL in the library. The method and system are configured to automatically locate the most likely fault location(s) by selecting the model GFL(s) that have the highest likelihood(s) of matching the real fault location-thus the model GFLs are compared with each other, and the model GFL with the maximum of the statistical property (compared to the other GFLs) is selected. A threshold may be used to select model GFL(s) with a pre-selected confidence level, at least in some implementations. The numerical/statistical property (determined by the function “g”) may include: (i) a selection of one or more values of each guessed fault signal, including selecting a central value at a central point (e.g., a mid-point of the guessed fault signal “r”); and/or (ii) determining an average value of two or more of the values of the guessed fault signal, including around the central value, which can be zero as shown in FIGS. 8A to 8F. The set of (real value) numbers representing the respective guessed fault signals can be represented as a vector of M values across the possible fault locations (“x”), e.g., as shown in FIGS. 9A to 9F.

The function “g” may include reducing the N×M real value numbers to a reduced subset (e.g., of the M real valued numbers) that summarises the likely location of the fault original in light of all observed signals (“s”) as a subset of the guessed fault real value numbers, e.g., as shown in the M-length vectors in FIGS. 10A and 10B reduced from the N×M arrays in FIGS. 9A to 9C, and FIGS. 9D to 9F, respectively. In this case, “g” function may include: (i) pairwise multiplication of each sensor's contribution to the guessed fault signal (at the fault location); (ii) biasing by a bias factor representing network distances between the N model observation points and the M model GLFs-thus represented in an N×M set of distance bias values; and/or (iii) biasing by a further bias factor representing a pre-selected error rate of the method, i.e., representing how frequently the method is to incorrectly estimate a fault location at a specified point.

This proposed method differs by not generating a simulated fault and comparing it directly to the observed signal, but instead filtering and back-injecting the observed signal to produce a new signal (“r”) at the guessed fault location (thus referred to as a “guessed fault signal”) that may be further processed.

### Example Implementations

The method may only require a single real observation point. Compared to previous methods that used many network monitoring points, the method described herein can reduce the number of calculations required, thereby minimizing the time to determine the location of the real fault. This could minimize the duration of power outages in the PLS. Further, the use of a single real observation point may reduce the cost of fault location, as only one real observation point needs to be equipped and maintained to record observed signals.

Implementation of the method described herein may allow for a PLS to host more renewable energy resources than use of existing methods.

The method described herein may be easily adaptable to grid changes in the PLS as the grid changes may be updated in the network model and the library of expected fault signals regenerated.

### Experimental Examples

In the following sections, the similarity metrics m₁ and m₂ are tested against some metrics defined in previous literature in the technical field, including FCSE (Fault Current Signal Energy) in reference [5], a similarity criterion suggested in reference [4] and a correlation suggested in reference [6]. First, the analytical equations are used to test the defined metrics in the simplified example. Then, the comparisons are carried out for a complex single phase system. Finally the metrics are tested on IEEE 34 bus system and compared.

### First Experimental Example: Analytic Test of m₁ and m₂

A simple single phase one line system may be used to test metrics m₁ and m₂ on an analytical level. The relevant parameters are as follows:
a. Line parameters:
   i. Line length (L)=8 km lossless single phase
   ii. Inductance per unit length (L′)=1.1 H/m
   iii. Capacitance per unit length (C′)=10.7 pF/m
   iv. The line is assumed to be terminated on both ends by power transformers which are modelled as high impedances Z0 and Z1, each 10 kΩ.
b. Fault description:
   i. Z_{f}=0, the test is repeated for 10Ω and 100Ω as well.
   ii. t_{f}=0.005 s (fault occurs at t=t_{f})
   iii. Actual fault location=5 km
c. Simulation description:
   i. Time step (dt)=10⁻⁶ s
   ii. GFLs (in km)=[0, 1, . . . 4, 4.5, 4.51, . . . 5.48, 5.49, 5.5, 6, 7, 8]

The maximum and minimum possible switching frequencies possible were 72.87 kHz and 9.1 kHz (based on the choice of guessed fault locations). The speed of the wave is 291482.02 km/s. Thus, a bandpass filter with a pass band of 8 kHz to 75 kHz suffices to capture all possible switching frequencies. This is utilised in calculating the metric m₂ for the analytical simple system.

FIGS. 1A and 1B show the performance of the metrics m₁ and m₂, respectively, when tested on the defined simple system for fault impedances of 0 Ω, 10Ω and 100Ω. The x-axis denotes the GFLs and the y-axis denotes the values for the metrics (normalised over all GFLs). The actual fault location was at x=5 km, marked with an star (*) in FIG. 1A, and with a cross (X) in FIG. 1B. The single observation point was at x=0 km. The analytical expressions, namely Equation (11) and Equation (12), are used. From these figures, it is implied that the metrics m₁ and m₂ exhibit very high accuracy in determining the actual fault location. In both FIGS. 1A and 1B, the highest value of similarity between the recorded observed signal and the expected fault signals occurs at a GFL very close to the actual fault location. FIG. 1A suggests that for the metric m₁ the most precise response occurs when the fault impedance is zero. However, the metrics both appear to be highly accurate in selecting the correct GFL for fault impedances of 10Ω and 100Ω as well.

$${V}_{{x}_{f}}^{DT} ( x = 0 , t ) = {\sum }_{j = 1}^{n} ( ( 1 + {Γ}_{0}^{V} ) {( {Γ}_{0}^{V} {Γ}_{{x}_{G} = {x}_{f}}^{V} )}^{j - 1} {V}_{f} ( t - ( 2 j - 1 ) {τ}_{{x}_{G} = {x}_{f}} ) ) \qquad ( 11 )$$

$${I}_{{x}_{G}}^{RT} ( ( x = {x}_{G} , t ) = {\sum }_{j = 1}^{n} ( ( 1 + {Γ}_{{x}_{G}}^{I} ) {( {Γ}_{0}^{I} {Γ}_{{x}_{G}}^{I} )}^{j - 1} {V}_{f} ( t - ( 2 j - 1 ) {τ}_{{x}_{G}} ) ) \qquad ( 12 )$$

FIG. 2A shows a comparison of the metrics m₁ and m₂ for a fault impedance of 100Ω, on the same simple system. The actual fault location was again at x=5 km, marked with a cross (X) in FIGS. 2A and 2B. and the single observation point is at x=0 km. From FIG. 2A it can be seen that m₂ is more selective than m₁. FIG. 2B shows the response of the same simple system for a fault impedance of 1000Ω. Since the characteristic impedance of the line is of the order of 10²Ω, the theoretical calculations for the case presented in FIG. 2B are faced with the problem that the fault impedance is greater than the characteristic impedance of the line. Therefore, it can no longer be assumed that voltage reflection coefficients at the actual fault location are close to −1. However, it is clear from FIGS. 1A-1B and 2A-2B that in an ideal system (with fault impedance sufficiently greater than the characteristic impedance of the line), the metrics are capable of estimating the actual fault location within a precision of around 50 m. This may allow estimation of the location of the fault where the fault currents are not very high relative to pre-fault conditions.

### Second Experimental Example: Testing m₁ and m₂ Against Other Methods

Existing methods have suggested other metrics to determine fault location. One is the FCSE which calculates the energy of a fault current for each GFL in the reversed time system and characterises the GFL associated with the maximum as the predicted fault location (reference [5]). Another is the correlation suggested in reference [6]. Another is the similarity criterion suggested in reference [4].

To show that m₁ and m₂ may be effective to locate faults in locations where the above previous methods fail, or give spurious peaks, a complex single phase network with multiple branches of transmission lines (each with a different characteristic impedance) may be used. FIGS. 3A and 3B, which connect at item 104 in FIG. 3A, show a schematic network model of such a system. The tested system of FIGS. 3A and 3B may be a medium voltage network, e.g., 11 kV. The tested system of FIGS. 3A and 3B is a single phase system with three branches to the main line, 34 guess fault locations separated by 1 km and line parameters as follows:

| line | L (H/km) | C (F/km) | length |
|---|---|---|---|
| 100-102 | 0.0009337 | 1.274E−08 | 3 |
| 102-106 | 0.00192 | 8.74E−09 | 6 |
| 102-104 | 0./0041264 | 7.751E−09 | 3 |
| 104-110 | 0.00492 | 6.74E−09 | 5 |
| 104-108 | 0.0061264 | 6.751E−09 | 5 |
| 108-114 | 0.00192 | 8.74E−09 | 7 |
| 108-112 | 0.00354 | 7.32E−09 | 9 |

Based on the above parameters, the calculated maximum and minimum switching frequencies of the system are 72.48 kHz (at 4 km) and 2.49 kHz (at 4 times (3+3+5+9)=80 km). The tested system may be used to calculate values for the different metrics.

FIGS. 4A-4F show the results comparing the other metrics with m₁ and m₂ for a number of actual fault positions in the tested system. In FIGS. 4A and 4C the actual fault location is at x=15, marked with a cross (X). In FIGS. 4B, 4D and 4F the actual fault location is at x=16, marked with a cross (X) or star (*). In FIG. 4E the actual fault location is at x=24, marked with a star (*). The x-axis denotes the 34 GFLs and the y-axis denotes the values for the metrics (normalised over all GFLs). FIGS. 4A and 4B show a comparison of the response of the described method using the FCSE method (labelled “energy” in the legend) to quantify the similarity between the recorded observed fault and the expected fault responses, with the response of m₁ and m₂. In FIG. 4A it may be seen that the FSCE method erroneously detects an additional fault at x=31. In FIG. 4B it may be seen that the FSCE method results in a spurious peak at x=13. FIGS. 4C and 4D show a comparison of the response of the described method using the similarity index of reference [4] with that using m₁ and m₂. In FIG. 4C the similarity index erroneously detects an additional fault at x=31. In FIG. 4D it may be seen that the similarity index results in a spurious peak at x=13. FIGS. 4E and 4F show a comparison of the response of the described method using the correlation metric of reference [6]. In FIG. 4E it may be seen that the correlation metric results in a spurious peak at x=28. In FIG. 4F it may be seen that the correlation metric results in a spurious peak at x=13. From FIGS. 4A-4F, it can be seen that the existing FCSE, similarity and correlation methods all result in strong spurious peaks when locating a fault in the tested system. This can result in the incorrect determination of the fault location.

Depending on the simulation software used and the complexity of the PLS network, testing for one fault location may take 250-260 seconds for the FCSE and similarity methods. For a network with a lot of guessed fault locations, these methods may involve a much longer locating time.

### Third Experimental Example: Testing on an IEEE 34 Bus System

The above metrics, along with m₁ and m₂ may also be tested on an IEEE 34-bus system simulated in a Simulink environment. FIGS. 5A to 5C are schematics of connected parts of the IEEE 34-bus system. The observation point may be located at 800. For the parameters of this system, a band pass filter of 2 kHz to 85 kHz was used. FIGS. 6A-6F show a comparison of the accuracy of m₁ and m₂ with the abovementioned FCSE metric for a fault in the IEEE 34-bus system. The x-axis denotes the actual fault location and the y-axis denotes GFLs. The calculated similarity is represented by the gradient of each data point, normalised over all actual fault locations, with the darkest data points having the highest similarity. FIGS. 6A and 6B shows the response of the FCSE method for fault impedances of 0Ω and 100Ω, respectively. It may be seen from FIGS. 6A and 6B that for a number of actual fault locations the FCSE method gives rise to many high similarity GFLs. This may make it difficult to accurately estimate the true location of the fault. FIGS. 6C and 6D show the response of m₂ for fault impedances of 0Ω and 100Ω, respectively. FIGS. 6E and 6F show the response of m₁ for fault impedances of 0Ω and 100Ω, respectively. It is clear that m₁ and m₂ give more satisfactory results than the FCSE method, although m₁ results in more spurious peaks than m₂ at locations further from the observation point. This could be attributed to the system where for locations farther from the real observation point, the switching frequencies are very close, which in turn means it is difficult to distinguish between two locations. The metric m₂ is more robust against this.

### Fourth Experimental Example: Comparison to Prior Method

In initial tests, an experimental example of the described method/system, using one sample network (35 db SNR and 3 sensors) and the library of model transfer functions ('h), was between 7.5-8.5 times better than abovementioned FCSE metric: e.g., the FCSE metric was only able to correctly locate ˜10-15% of the faults, compared to ˜100% for the newly proposed method, where ‘locate’ means the predicted GFL is exactly the true GFL. Initial tests of experimental examples of the described method/systems using m1 and m2 performed similarly well (˜100%).

### Interpretation

Many modifications will be apparent to those skilled in the art without departing from the scope of the present invention. For example, the steps of the method may be performed in a different order from that described hereinbefore; however, it may be preferable to generate the library before the real fault occurs, thus before receiving the observed signal.

The presence of “/” in a FIG. or text herein is understood to mean “and/or” unless otherwise indicated, i.e., “A/B” is understood to mean “A” or “B” or “A and B”. The recitation of a particular numerical value or value range herein is understood to include or be a recitation of an approximate numerical value or value range, for instance, within +/−20%, +/−15%, +/−10%, +/−5%, +/−2.5%, +/−2%, +/−1%, +/−0.5%, or +/−0%. The term “essentially all” or “substantially” can indicate a percentage greater than or equal to 50%, 60%, 70%, 80%, or 90%, for instance, 92.5%, 95%, 97.5%, 99%, or 100%.

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

### Statements

Aspects of the present disclosure may be summarized by the following numbered statements:

Statement 1: A method of fault location in an electrical power line system (PLS), the method including:
receiving an observed signal caused by a real fault in the PLS, wherein the observed signal is measured at at least one real observation point in the PLS;
accessing a library representing a plurality of expected fault signals at respective model guessed fault locations (model GFLs) in a network model of the PLS;
selecting at least a most similar one of the plurality of expected fault signals to the observed signal;
estimating a fault location of the real fault in the PLS by selecting the model GFL that corresponds to the most similar one of the plurality of expected fault signals; and
   sending the estimated fault location to an external management system to respond to the real fault.

Statement 2. The method of Statement 1, wherein the expected fault signals are generated, for the plurality of model GFLs in the network model, by:
injecting a test pulse at a model observation point of the network model, wherein the model observation point corresponds to the real observation point of the PLS;
recording respective test responses to the test pulse at the model GFLs; and
calculating, from the recorded test responses, respective expected fault signals for the model GFLs.

Statement 3. The method of Statement 1 or 2, wherein the selecting of the at least a most similar one of the plurality of expected fault signals to the observed signal is by:
comparing the observed signal to the plurality of expected fault signals to generate a plurality of respective similarity values according to a selected similarity metric, and
selecting at least one of the plurality of expected fault signals corresponding to a selected one of the plurality of similarity values representing a highest similarity according to the selected similarity metric.

Statement 4. The method of Statement 3, wherein the similarity values are calculated based on a peak value of a correlation between the observed signal and the plurality of expected fault signals, and/or based on a relationship with a time delay when the peak value occurs.

Statement 5. The method of Statement 3, wherein the similarity values are calculated based on a relationship with an energy in a difference signal between the observed signal and the plurality of expected fault signals, optionally including calculating the difference signal using a bandpass filter.

Statement 6. A method of generating a plurality of expected fault signals for a real observation point of an electrical power line system (PLS), the method including:
defining a network model of the PLS representing:
   a model observation point corresponding to the real observation point of the PLS, and
   a plurality of model guessed fault locations (model GFLs) corresponding to respective real guessed fault locations (real GFLs) in the PLS;
injecting a test pulse at the model observation point of the network model;
recording respective test responses to the test pulse at the model GFLs;
calculating, from the recorded test responses, respective expected fault signals at the model GFLs; and
generating a library representing the plurality of expected fault signals for locating a real fault in the PLS by selecting a most similar one of the plurality of expected fault signals to an observed signal caused by the real fault at the real observation point, and estimating the fault location of the real fault by selecting the model GFL that corresponds to the most similar one of the plurality of expected fault signals.

Statement 7. Computer readable storage having stored thereon computer-executable instructions which, when executed by a computing system, cause the computing system to execute the method of any one of Statements 1 to 6.

Statement 8. A system for fault location in an electrical power line system (PLS), the system including:
a computing system configured to execute the method of any one of Statements 1 to 5.

Statement 9. The system of Statement 8 including: a voltage monitoring system attached to the PLS configured to monitor the observed signal; and a data acquisition system configured to send the observed signal from the voltage monitoring system to the computing system.

Statement 10. A method of fault location in an electrical power line system (PLS), the method including:
receiving at least one observed signal caused by a real fault in the PLS, wherein the observed signal is measured at a real observation point in the PLS, and wherein the real fault has occurred at one of two or more real locations in the PLS;
accessing a library representing a plurality of model signals between respective model guessed fault locations (model GFLs, which correspond to the real locations) and model observation points (which correspond to the real observation points) in a network model of the PLS, wherein the model signals include:
   (i) expected fault signals (or “model fault signals”) generated from the network model, and/or
   (ii) model transfer functions (labelled “h” herein, also referred to as “impulse responses”) between the model GFLs and model observation points generated from the network model;
selecting at least one of the model GFLs by:
   (i) selecting at least a most similar one of the plurality of model signals to the observed signal, and selecting the model GFL(s) that correspond to the selected model signal(s), and/or
   (ii) determining guessed fault signals (labelled “r” herein) at the model GFLs for each observed signal (including by combining the observed signal with the model transfer functions), and selecting at least one of the model GFLs corresponding to the guessed fault signals having at least one property (e.g., a statistical property);
estimating a fault location of the real fault in the PLS by selecting the model GFL that corresponds to the most similar one of the plurality of expected fault signals; and
sending the estimated fault location to an external management system to respond to the real fault.

Statement 11. A method of generating a plurality of model signals at a real observation point of an electrical power line system (PLS), the method including:
defining a network model of the PLS including:
   a model observation point corresponding to the real observation point of the PLS, and
   a plurality of model guessed fault locations (model GFLs) corresponding to respective real expected fault locations (real GFLs) in the PLS;
injecting a test pulse at the model observation point of the network model;
recording respective test responses to the test pulse at the model GFLs;
calculating, from the recorded test responses, respective expected fault signals at the model GFLs; and
generating a library representing the plurality of expected fault signals for locating a real fault in the PLS by selecting a most similar one of the plurality of expected fault signals to an observed signal caused by the real fault at the real observation point, and estimating the fault location of the real fault by selecting the model GFL that corresponds to the most similar one of the plurality of expected fault signals.

Statement 12. According to at least one embodiment of the present invention there is further provided a method of generating a plurality of model signals at a real observation point of an electrical power line system (PLS), the method including:
defining a network model of the PLS including:
   a model observation point corresponding to the real observation point of the PLS, and
   a plurality of model guessed fault locations (model GFLs) corresponding to respective real expected fault locations (real GFLs) in the PLS;
injecting a test pulse at the model observation point of the network model;
recording respective test responses to the test pulse at the model GFLs;
calculating, from the recorded test responses, respective model transfer functions between the model GFLs and model observation points; and
generating a library representing the plurality of model signals for locating a real fault in the PLS by determining guessed fault signals (“r”) at the model GFLs for each observed signal (including by combining the observed signal with the model transfer functions), and selecting at least one of the model GFLs corresponding to the guessed fault signals having at least one property.

### REFERENCES

The references are:
[1]M. Rubinstein, F. Rachidi, and M. Paolone, Electromagnetic Time Reversal: Application to Electromagnetic Compatibility and Power Systems, New York: Wiley, 2017.
[2]J. de Rosny, G. Lerosey and M. Fink, “Theory of Electromagnetic Time-Reversal Mirrors,” in IEEE Transactions on Antennas and Propagation, vol. 58, no. 10, pp. 3139-3149, October 2010.
[3]A. Orlandi, F. Rachidi and M. Paolone, “Extension of the Unmatched-Media Time Reversal Method to Locate Soft Faults in Transmission Lines,” in IEEE Transactions on Electromagnetic Compatibility, vol. 60, no. 5, pp. 1539-1545, October 2018. doi: 10.1109/TEMC.2018.2799932
[4]Z. Wang, R. Razzaghi, M. Paolone and F. Rachidi, “Electromagnetic Time Reversal Applied to Fault Location: On the Properties of Back-Injected Signals,” 2018 Power Systems Computation Conference (PSCC), Dublin, 2018, pp. 1-7.
[5]R. Razzaghi, G. Lugrin, H. Manesh, C. Romero, M. Paolone, and F. Rachidi, “An efficient method based on the electromagnetic time reversal to locate faults in power networks,” IEEE Transactions on Power Delivery, vol. 28, no. 3, pp. 1663-1673, 2013.
[6]S. He, A. Cozza and Y. Xie, “Electromagnetic Time Reversal as a Correlation Estimator: Improved Metrics and Design Criteria for Fault Location in Power Grids,” in IEEE Transactions on Electromagnetic Compatibility.
[7]A. Borghetti, M. Bosetti, M. Di Silvestro, C. A. Nucci and M. Paolone, “Continuous-Wavelet Transform for Fault Location in Distribution Power Networks: Definition of Mother Wavelets Inferred From Fault Originated Transients,” in IEEE Transactions on Power Systems, vol. 23, no. 2, pp. 1-388, May 2008.

### COMPUTER PROGRAM APPENDIX

A. m1_metric.m

| | |
|---|---|
| 159 | for guess = 1:length(guess_array) |
| 160 | expected_response_full(:,guess) = conv(fault_v,Hrt(:,guess)); |
| 161 | expected_response(:,guess) = expected_response_full(0.01/dt+1:0.06/dt,guess); |
| | [r1(:,guess,k),lags1] = |
| 162 | xcov(fault_voltage_data(0.01/dt:end,k)/max(fault_voltage_data(0.01/dt:end,k)), |
| | expected_response(0.01/dt:end,guess)/max(expected_response(0.01/dt:end,guess)), |
| | 120000,‘coeff’); |
| 163 | corr_val(guess,k) = max(r1(:,guess,k)); |
| 164 | time_delay(guess,k) = lags1(1,r1(:,guess,k) == max(r1(:,guess,k))); |
| 165 | end |
| 166 | end |
| 167 | m1 = abs(log(1 − corr_val))./ (1+abs(time_delay)); |

B. m2_metric.m

| | |
|---|---|
| 149 | for guess = 1:length(guess_array) |
| 150 | % calculate expected transients by convolution |
| 151 | expected_response_full(:,guess) = conv(fault_v,Hrt(:,guess)); |
| 152 | expected_response(:,guess) = expected_response_full(0.01/dt:0.1/dt,guess); |
| 153 | %align signals based on delay |
| | [a(1:length(expected_response),guess,k),b(1:length(expected_response),guess,k) |
| 154 | ] = alignsignals(expected_response(:,guess), |
| | fault_voltage_data(0.01/dt:end,k),[ ],‘truncate’); |
| 155 | error(:,guess,k) = (a(:,guess,k)/max(a(:,guess,k))- |
| | b(:,guess,k)/max(b(:,guess,k))); |
| 156 | % filter the error |
| 157 | filerr(:,guess,k) = conv(error(:,guess,k),h1); |
| 158 | |
| 159 | error_energy(guess,k) = sum(filerr(:,guess,k).\hat{ }2); |
| 160 | end |
| 161 | end |
| 162 | |
| 163 | param2 = 1./(1 + abs(error_energy)); |

C. transform.m

| | |
|---|---|
| 60 | for i=1:observation_points |
| 61 | |
| 62 | h = h_library{i}; |
| 63 | filt_v = diff(fault_v(:, i)); |
| 64 | |
| 65 | r = [ ]; |
| 66 | for j=1:GFL |
| 67 | r_sig = conv(flip(filt_v), h(:, j)); |
| 68 | r = [r, r_sig(length(filt_v)+1)]; |
| 69 | end |
| 70 | R = [R; abs(r)]; |
| 71 | end |
| 72 | |
| 73 | x = ones(1, GFL); |
| 74 | for i=1:observation_points |
| 75 | x = x.*R(i, :); |
| 76 | end |

1. A method of fault location in an electrical power line system (PLS), the method including:
receiving at least one observed signal caused by a real fault in the PLS, wherein the or each observed signal is measured at a real observation point in the PLS, and wherein the real fault has occurred at one of two or more real locations in the PLS;
accessing a library representing a plurality of model signals between model guessed fault locations and at least one model observation point in a network model of the PLS;
selecting at least one of the model GFLs by:
(i) calculating metrics for the model signals by processing the model signals with the or each observed signal according to a pre-selected mathematical relationship/operation, and/or
(ii) selecting the at least one model GFL corresponding to at least one highest one of the calculated metrics;
estimating at least one fault location of the two or more real locations in the PLS based on at least one corresponding location of the at least one selected model GFL; and
sending the or each estimated fault location to an external management system to respond to the real fault.

2. The method of claim 1, wherein the model signals include expected fault signals at the at least one model observation point.

3. The method of claim 2, wherein the calculating of the metrics and selecting of the at least one model GFL includes selecting at least a most similar one of the plurality of model signals to the or each observed signal, and selecting the at least one model GFL that correspond to the at least one selected model signal.

4. The method of claim 3, wherein the metrics include similarity metrics representing a similarity between each expected fault signal and the or each observed signal.

5. The method of claim 4, wherein the pre-selected mathematical relationship/operation includes: a correlation between each expected fault signal and the or each recorded observed signal; and/or energy in a difference signal between each expected fault signal and the or each recorded observed signal.

6. The method of claim 1, wherein the model signals include model transfer functions between the model GFLs and the at least one model observation point.

7. The method of claim 6, wherein the calculating of the metrics and the selecting of the at least one model GFL includes determining guessed fault signals at the model GFLs for the or each observed signal, and selecting at least one of the model GFLs corresponding to at least one of the guessed fault signals having at least one property of the guessed fault signals, optionally a highest determined numerical value of the property.

8. The method of claim 7, wherein the metrics include numerical values of a selected property of the guessed fault signals determined by combining the or each observed signal with each of the model transfer functions.

9. The method of claim 8, wherein the selecting of the at least one model GFL includes: determining the guessed fault signals at the model GFLs by combining the or each observed signal with each model transfer function, and determining a numerical value of the property for each guessed fault signal, and selecting the at least one model GFL corresponding to the highest of the numerical values.

10. The method of claim 9, wherein the values of the property of the guessed fault signals, including in a reduced subset of the guessed fault signals, are determined according to the mathematical relationship/ope/ration, wherein the mathematical relationship has a numerical/statistical operation.

11. The method of claim 10, wherein the pre-selected mathematical relationship/operation includes:
the combining of each model transfer function and the recorded observed signal, optionally including a reverse time convolution of the or each observed signal and/or a derivative of the or each observed signal; and/or
a numerical/statistical operator for the combining, optionally selection of a central value and/or determining an average value.

12. A method of generating a plurality of model signals at a real observation point of an electrical power line system (PLS), the method including:
defining a network model of the PLS including:
(i) one or more model observation points corresponding to the real observation points of the PLS, and
(ii) a plurality of model guessed fault locations (model GFLs) corresponding to respective real expected fault locations (real GFLs) in the PLS;
injecting a test pulse at the model observation point of the network model;
recording respective test responses to the test pulse at the model GFLs;
calculating, from the recorded test responses, respective model signals for each model GFL paired with the or each model observation point; and
generating a library representing the plurality of model signals for locating a real fault in the PLS based on estimating a location of the real fault by selecting at least one of the model GFLs that corresponds to at least one of the model signals selected by calculating metrics for the model signals by processing the model signals with at least one observed signal caused by the real fault at the real observation point according to a pre-selected mathematical relationship/operation.

13. The method of claim 12, wherein the model signals include expected fault signals, the calculating includes calculating, from the recorded test responses, respective expected fault signals at the model GFLs, and the metrics include similarity metrics representing a similarity between each expected fault signals and the or each observed signal.

14. The method of claim 12, wherein the model signals include model transfer functions between the model GFLs and model observation points, the calculating includes calculating, from the recorded test responses, respective model transfer functions between the model GFLs and model observation points, and the metrics include numerical values of a selected property of guessed fault signals at the model GLFs.

15. A computer-readable storage medium having stored thereon computer-executable instructions that cause a computing system to execute the method of claim 1.

16. A system for fault location in an electrical power line system (PLS), the system including:
a computing system configured to execute the method of claim 1;
a voltage monitoring system attached to the PLS configured to monitor the observed signal; and
a data acquisition system configured to send the observed signal from the voltage monitoring system to the computing system.
